(19) United States
(12) Patent Application Publication
(10) Pub. No.: US 2014/0052395 A1
(43) Pub. Date: Feb. 20, 2014

(54) METHOD AND APPARATUS FOR ESTIMATING THE REMAINING TIME REQUIRED TO FULLY CHARGE A BATTERY, AND MOBILE DEVICE INCORPORATING THEREOF

(71) Applicants: Shell Internet (Beijing) Security Technology Co.,, Beijing (CN); Conew Network Technology (Beijing) Co., Ltd., Beijing (CN); Beijing Kingsoft Internet Security Software Co., Ltd., Beijing (CN)

(72) Inventors: Tao HAN, Beijing (CN); Ming XU, Beijing (CN); Yunfei LU, Beijing (CN)

(73) Assignees: Shell Internet (Beijing) Security Technology Co., Ltd., Beijing (CN); Conew Network Technology (Beijing) Co., Ltd., Beijing (CN); Beijing Kingsoft Internet Security Software Co., Ltd., Beijing (CN)

(21) Appl. No.: 13/970,407

(22) Filed: Aug. 19, 2013

(30) Foreign Application Priority Data
Aug. 20, 2012 (CN) 201210297383.4

(51) Int. Cl. G01R 31/36

(52) U.S. Cl. CPC G01R 31/3606
USPC 702/63

(57) ABSTRACT

A method, an apparatus and a mobile device estimate remaining time required to fully charge a battery. The method may include (a) determining from one or more of the mobile device's charging records the time required for charging the battery of the mobile device by one unit of charge (“unit charging time”); and (b) based on the time so determined, calculating the remaining time required for fully charging the mobile device's battery. In this manner, an accurate estimate of the remaining charging time is achieved. In one instance, the charging record includes the initial charge (A) in the battery, expressed as a percentage of the full capacity, the final charge (B) in the battery at the end of the charging, also expressed as a percentage of full capacity, and the total charging time required (T). Each unit of charge may be, for example, 1% of the full charge of the battery.

### CROSS-REFERENCE TO RELATED APPLICATIONS

The present application relates to and claims priority of Chinese Patent Application, No. 201210297383.4, entitled “Battery Charge Remaining Time Estimation Method, apparatus and mobile device” filed on Aug. 20, 2012. The disclosure of the Chinese Patent Application is hereby incorporated herein by reference in its entirety.

### BACKGROUND OF THE INVENTION

1. Field of the Invention

The present invention relates to estimating the time remaining to fully charge a battery. In particular, the present invention relates to estimating the remaining time for fully charging a battery in a mobile device (e.g., a cellular telephone).

2. Discussion of the Related Art

As the mobile platform and its equipment have become pervasive, battery charging has become an essential activity in the everyday use of a mobile telephone. To better assist a user in managing his or her time, it would be important that the remaining charging time required is displayed to the user during the course of battery charging. Existing methods for estimating remaining charging time do not take into account the method used for charging. However, the charging times for charging directly from an AC outlet and for charging through a USB connection to a computer are significantly different. The prior art uses an empirically determined average charging time from which the remaining charging time is obtained by dynamic adjustment in the course of the battery charging process. Such an approach, however, do not take into consideration the characteristics of different platforms and the variation among the devices. Consequently, the estimated remaining charging time varies significantly from the actual remaining charging time, thus reducing the usefulness of the estimate.

### SUMMARY

The invention provides a method, an apparatus and a mobile device for estimating remaining time required to fully charge a battery. According to one embodiment of the present invention, the method may include (a) determining from one or more of the mobile device's charging records the time required for charging the battery of the mobile device by one unit of charge (“unit charging time”); and (b) based on the time so determined, calculating the remaining time required for fully charging the mobile device's battery. The present invention provides an accurate estimate of the remaining charging time. In one instance, the charging record includes the initial charge (A) (i.e., the charge in the battery at the beginning of charging), expressed as a percentage of the full capacity, the final charge (B) (i.e., the charge in the battery at the completion of charging), also expressed as a percentage of full capacity, and the total elapsed time (T) between the beginning of charging and the completion of charging. Each unit of charge may be, for example, 1% of the full charge of the battery.

According to one embodiment of the present invention, an acceptable charging record for calculating remaining charging time is one in which the initial charge is less than a first value, the final charge B substantially equals a second value, and the elapsed time T is less than a predetermined length. Further, the unit charging time for charging may be provided by:

$$C = \frac{{\sum }_{i = 1}^{n} {T}_{i}}{{\sum }_{i = 1}^{n} ( {B}_{i} - {A}_{i} )}$$

where n is the number of charging records, Tᵢ is the total elapsed time recorded in the ith charging record, Aᵢ is the initial charge recorded in the ith charging record, and Bᵢ is the final charge recorded in the ith charging record, both Aᵢ and Bᵢ being expressed as percentages of the full charge. The remaining charging time t may therefore be calculated by:

t=(100−X)×C

where X is the current charge in the battery, expressed as a percentage of the full charge, i.e., 0<X<100.

According to one embodiment of the present invention, an apparatus and a mobile device each can be provided incorporating the method for calculating the remaining charge set forth above.

By first determining an unit charging time for a battery of a mobile device from accumulated charging records, and then using the determined unit charging time to calculate the remaining charging time, a method of the present invention dynamically adjusting the unit charging time based on previous charging records, resulting in obtaining a more accurate remaining charge time.

The present invention is better understood upon consideration of the detailed description below in conjunction with the accompanying drawings.

### BRIEF DESCRIPTION OF THE DRAWINGS

FIG. 1 is a flow chart of method 100 for calculating a remaining charging time, in accordance with one embodiment of the present invention.

FIG. 2 is a flow chart of method 200 for calculating a remaining charging time, in accordance with one embodiment of the present invention.

FIG. 3 illustrates a model relating the charge in a battery of a mobile device and the charging time, in accordance with one embodiment of the present invention.

FIG. 4 illustrates this calculation of unit charging time C with two battery charging records represented by models 401 and 402.

FIG. 5 illustrates apparatus 500 for calculating remaining charging time, according to one embodiment of the present invention.

FIG. 6 shows block diagram 600 of a mobile device into which a method of the present invention may be incorporated.

### DETAILED DESCRIPTION OF THE PREFERRED EMBODIMENTS

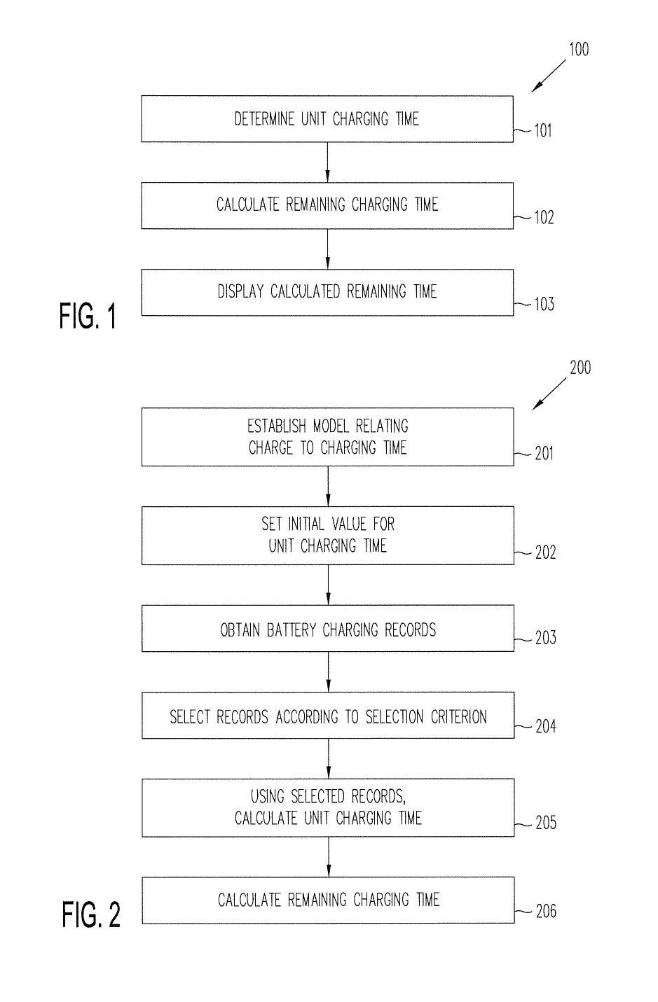

FIG. 1 is a flow chart of method 100 for calculating a remaining charging time of a battery in a mobile device, in accordance with one embodiment of the present invention. As shown in FIG. 1, at step 101, determining an charging time C for a unit of charge (“unit charging time”) in the battery, based on charging records obtained for the battery of the mobile device. At step 102, based on the unit charging time C thus determined, calculating the remaining charging time t. At step 103, displaying the calculated remaining charging time on a display of the mobile device.

By first determining a unit charging time for battery of a mobile device from charging records, and then using the determined unit charging time to calculate the remaining charging time, a method of the present invention dynamically adjusts the unit charging time based on previous charging records, resulting in a more accurate remaining charge time estimation.

According to another embodiment of the invention, step 101 may include the step of collecting one or more battery charging records, including records that provide an initial charge (A) of the battery at the beginning of charging, expressed as a percentage of the full capacity, a final charge (B) in the battery at the completion of charging, also expressed as a percentage of full capacity, and the total elapsed time (T) between the beginning of the charging and the completion of the charging. In one embodiment, a selection criterion is applied to the records to obtain only those records that are acceptable for calculating the unit charging time. The selection criterion may be, for example: initial charge A is less than a first value, final charge B substantially equals a second value, and total time T is not greater than a predetermined length.

In one embodiment, step 101 of method 100 may include: unit charging time C, which may be obtained by:

$$C = \frac{{\sum }_{i = 1}^{n} {T}_{i}}{{\sum }_{i = 1}^{n} ( {B}_{i} - {A}_{i} )}$$

where n is the number of charging records, Tᵢ is the total elapsed time recorded in the ith charging record, Aᵢ is the initial charge recorded in the ith charging record, and Bᵢ is the final charge recorded in the ith charging record, both Aᵢ and Bᵢ being expressed as percentages of the full charge. Further, step 102 may include calculating the remaining charging time t by:

t=(100−X)×C

where X is the current charge in the battery, expressed as a percentage of the full charge, i.e., 0<X<100.

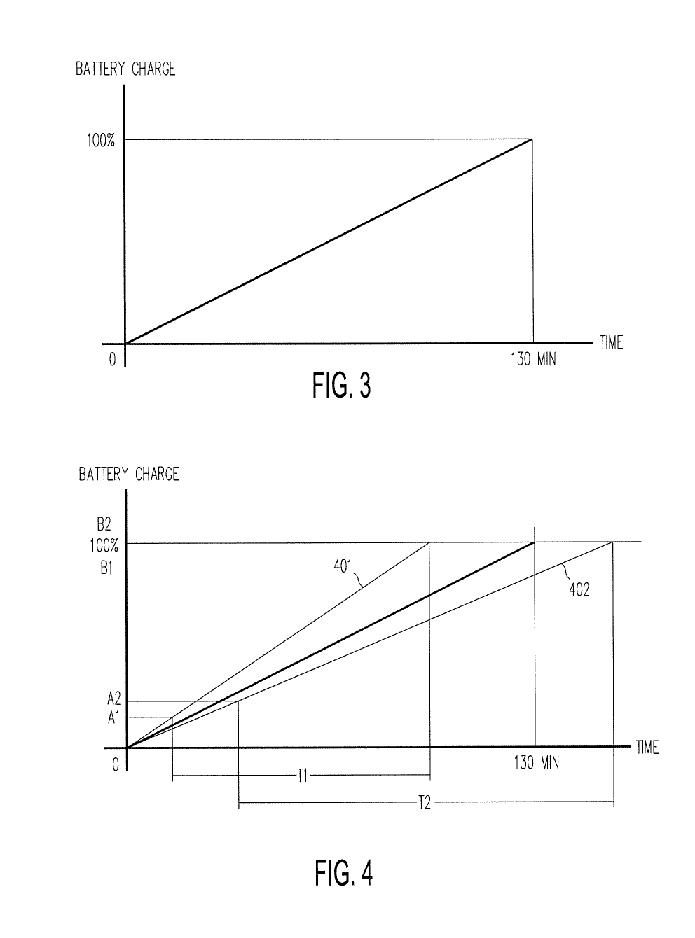

FIG. 2 is a flow chart of method 200 for calculating a remaining charging time, in accordance with another embodiment of the present invention. As shown in FIG. 2, at step 201, a model is established relating the charge in the battery of the mobile device (e.g., as a percentage of full charge) and the charging time. FIG. 3 illustrates model 300 relating the charge in the battery of the mobile device and the charging time, in accordance with one embodiment of the present invention. As shown in FIG. 3, model 300 is a linear model, in which the charging time of the mobile device's battery increases linearly until charging is completed (i.e., the charge capacity, expressed as a percentage of full charge, reaches 100%).

At step 202, an initial value for unit charging time C required is selected. The unit charging time is the charging time for charging a battery by a unit of charge (e.g., 1% of the full charge of a battery). For example, a default value m may be selected for the time required to charge the battery from 0 to 100% of full charge. In one implementation, m is selected to be 130 minutes, so that the initial value for C may be set as 130/(100−0)=1.3 minutes.

At step 203, the battery charging records of the mobile device are obtained. Such records may be made after completion of a charging. Each charging record may include, for example, initial charge A at the time the charging began, expressed as a percentage of full charge, final charge B at the completion of charging, expressed as a percentage of full charge, and total elapsed time T, being the time that elapse while bringing the battery of the mobile device from initial charge A to final charge B.

At step 204, the obtained battery charging records are screened according to a selection criterion to obtain a set of acceptable battery charging records. Specifically, one example for the selection criterion may be initial charge A being less than 20%, final charge B being 100%, and total charging time T not being greater than 240 minutes.

Selecting records in which the initial charge and the final charge differs by a sufficiently large amount ensures that the selected charging records are more likely to provide accuracy. Selecting a maximum of 240 minutes for elapsed time T excludes the effects of abnormal charging conditions. Of course, these values selected for parameters A, B and T are merely exemplary, suitable actual values for parameters A, B and T may be empirically determined.

At step 205, according to the battery charging records obtained at step 204, the unit charging time C is adjusted. If there is only one acceptable battery charging record, unit charging time C may be provided by:

C=Tᵢ/(B₁−A₁)

If there are two acceptable battery charging records, unit charging time C may be provided by:

C=(T₁+T₂)/((B₁−A₁)+(B₂−A₂))

FIG. 4 illustrates this calculation of unit charging time C with two battery charging records represented by models 401 and 402. Generally, unit charging time C for n records may be obtained by:

$$C = \frac{{\sum }_{i = 1}^{n} {T}_{i}}{{\sum }_{i = 1}^{n} ( {B}_{i} - {A}_{i} )}$$

where n is the number of charging records, Tᵢ is the elapsed time recorded in the ith charging record, Aᵢ is the initial charge recorded in the ith charging record, and Bᵢ is the final charge recorded in the ith charging record, both Aᵢ and Bᵢ being expressed as percentages of the full charge.

At step 206, the current remaining time t may be calculated using unit charging time C:

t=(100−X)×C

where X is the current charge in the battery, expressed as a percentage of the full charge, i.e., 0<X<100.

Then the calculated current remaining time t is displayed on a display of the mobile device.

The present invention avoids inaccuracy in estimating the remaining charging time due to variations across different platforms and devices. Inaccuracy is avoided by using, in each platform or device, previous charging records of that platform or device to dynamically adjust and improve the unit charging time obtained, and thereby providing a method for accurately estimating the remaining charging time. Through this technical solution, a method of the present invention avoids the specific individual characteristics of each device, to provide the most reasonable and the most accurate standard calculation of the remaining charging time.

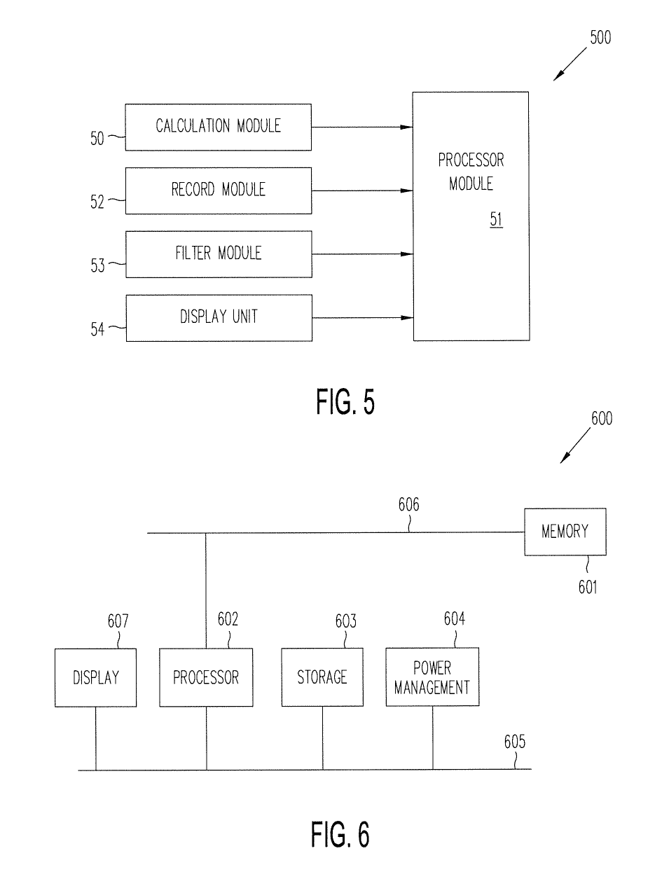

FIG. 5 illustrates apparatus 500 for calculating remaining charging time, according to one embodiment of the present invention. As shown in FIG. 5, apparatus 500 includes calculation module 50, which calculates a unit charging time C based on battery charging records, and processing module 51, which calculates remaining charging time t based on the unit charging time calculated in calculation module 50, and a display unit 54 which displays the remaining charging time for charging the battery calculated in processing module 51. Calculation module 50 and processing module 51 calculates unit charging time C and remaining charging time t using the methods described above.

Furthermore, apparatus 500 may further include record module 52 and filter module 53. Record module 52 stores battery charging records. Each battery charging record may include initial charge A of the battery at the start of the charging operation, final charge B at the end of the charging operation, and elapsed time T. Filter module 53 applies a selection criterion to obtain acceptable battery charging records. One selection criterion selects battery charging record that show initial charge A that is less than a first value, final charge B substantially equals a second value, with elapsed time T not greater than a predetermined length of time.

The apparatuses within the scope of the present invention may implement corresponding methods of the present invention described above, and achieve corresponding technical effects. The apparatuses may be incorporated into various mobile devices, including smart telephones, tablet computers and other electronic mobile devices. In one implementation, an apparatus of the present invention may be incorporated into a battery management module. For example, FIG. 6 shows block diagram 600 of relevant circuits in a mobile device into which a method of the present invention is incorporated. As shown in FIG. 6, the mobile device may include processor 602 having access to memory unit 601 over memory bus 606, storage medium 603, power management system 604 and display unit 607 over peripheral bus 605. In this implementation, the physical process of battery charging is carried out by power management system 604 which may report a charge condition of a battery (e.g., in terms of % of full charge) and battery charging parameters, such as charging time. Based on data obtained from power management system 604, processor 602 may store a battery charging record upon completion of each battery charging in storage medium 603. The executable instructions for retrieving such battery charging records from storage medium 603, for calculating a unit charging time and for calculating the remaining charging time may be stored in storage medium 603. These executable instructions may be stored in storage medium 603 and may be loaded into memory 601 for execution by processor 602.

In this detailed description, certain features are referred to as modules to emphasize that these features may be independently implemented.

These modules may be implemented in software and can be executed in all types of processors. For example, a representative module may be structured as computer executable instructions in one or more physical or logical blocks, including objects, procedures, or functions. The modules need to be located into a single locale, and may be distributed for execution at different locales to achieve the purposes of the present invention. The modules of computer executable instructions may include one or more instructions in one or more procedures, stored in one or more storage media. Similarly, operational data may be identified in the modules, and may be implemented in any suitable form and organized in any suitable type of data structure. The operation data may be collected as a single data set, or may be distributed in different locations (including different storage devices), and at least partially be present as electronic signals on a system or network.

When any module described above is implemented by software, taking into account the level of skill in existing hardware technology and without considering cost, one skilled in the art may provide corresponding hardware circuits to achieve corresponding functions of the module. Such hardware circuits may include conventional very large scale integration (VLSI) circuits or gate arrays, and as logic integrated circuits, transistors circuits and the like implemented in conventional semiconductor or other discrete components. Modules may also be implemented in programmable hardware devices, such as field programmable gate arrays, programmable array logic, programmable logic devices or the like.

In the methods according to various embodiments of the present invention described above, unless specifically provided, the steps may be carried out in any order.

The detailed description above is provided to illustrate the specific embodiments and is not intended to be limiting. Numerous modifications, improvements and variations within the scope of the present invention are possible. The present invention is set forth in the accompanying claims.

We claim:

1. In a mobile device, a method for estimating remaining charging time of a battery, comprising:
based on battery charging records in the mobile device, determining a unit charging time for the battery;
based on the unit charging time, calculating the remaining charging time for charging the battery; and
displaying the calculated remaining charging time on a display of the mobile device.

2. The method of claim 1, wherein each battery charging record comprises data representing:
an initial charge of the battery at the beginning of charging;
a final charge of the battery at completion of charging; and
an elapsed time between the beginning of charging and the completion of charging.

3. The method of claim 1, wherein the battery charging records used to determine the unit charging time are selected according to a selection criterion.

4. The method of claim 3, wherein the selection criterion selects a record in which the initial charge is less than a first value, the final charge is substantially equal to a second value, and the elapsed time is not greater than a predetermined value.

5. The method of claim 2, wherein the unit charging time is determined according to
$$C = \frac{{\sum }_{i = 1}^{n} {T}_{i}}{{\sum }_{i = 1}^{n} ( {B}_{i} - {A}_{i} )}$$
where n is the number of charging records, Tᵢ is the elapsed time recorded in the ith charging record, Aᵢ is the initial charge recorded in the ith charging record, and Bᵢ is the final charge recorded in the ith charging record, both Aᵢ and Bᵢ being expressed as percentages of the full charge.

6. The method of claim 5, wherein the remaining charging time t is calculated using t=(100−X)×C, where X is a current charge expressed as percentage of full charge in the battery of a mobile device, 0<X<100.

7. An apparatus in a mobile device including a battery, comprising:
a calculating module which, based on battery charging records in the mobile device, determines a unit charging time for the battery;
a processing module which, based on the unit charging time, calculates the remaining charging time for charging the battery; and
a display unit which displays the calculated remaining charging time for charging the battery.

8. The apparatus of claim 7, wherein each battery charging record comprises data representing:
an initial charge of the battery at the beginning of charging;
a final charge of the battery at completion of charging; and
an elapsed time between the beginning of charging and the completion of charging.

9. The apparatus of claim 7, wherein the battery charging records used to determine the unit charging time are selected according to a selection criterion.

10. The apparatus of claim 9, wherein the selection criterion selects a record in which the initial charge is less than a first value, the final charge is substantially equal to a second value, and the elapsed time is not greater than a predetermined value.

11. The apparatus of claim 8, wherein the unit charging time is determined according to
$$C = \frac{{\sum }_{i = 1}^{n} {T}_{i}}{{\sum }_{i = 1}^{n} ( {B}_{i} - {A}_{i} )}$$
where n is the number of charging records, Tᵢ is the elapsed time recorded in the ith charging record, Aᵢ is the initial charge recorded in the ith charging record, and Bᵢ is the final charge recorded in the ith charging record, both Aᵢ and Bᵢ being expressed as percentages of the full charge.

12. The apparatus of claim 11, wherein the remaining charging time t is calculated using t=(100−X)×C, where X is a current charge expressed as percentage of full charge in the battery of a mobile device, 0<X<100.

13. A mobile device including a battery, comprising:
a processor;
a memory unit accessible by the processing unit for instructions executable by the processor; and
a storage medium storing in a non-transitory manner the instructions executable by the processing unit and from which the processor loads the executable instructions into the memory for execution, wherein the executable instructions embodies a method which comprises:
based on battery charging records in the mobile device, determining a unit charging time for the battery;
based on the unit charging time, calculating the remaining charging time for charging the battery; and
displaying the remaining charging time on a display of the mobile device.

14. The mobile device of claim 13, wherein each battery charging record comprises data representing:
an initial charge of the battery at the beginning of charging;
a final charge of the battery at completion of charging; and
an elapsed time between the beginning of charging the completion of charging.

15. The mobile device of claim 13, where in the battery charging records used to determine the unit charging time are selected according to a selection criterion.

16. The mobile device of claim 15, wherein the selection criterion selects a record in which the initial charge is less than a first value, the final charge is substantially equal to a second value, and the elapsed time is not greater than a predetermined value.

17. The mobile device of claim 14, wherein the unit charging time is determined according to
$$C = \frac{{\sum }_{i = 1}^{n} {T}_{i}}{{\sum }_{i = 1}^{n} ( {B}_{i} - {A}_{i} )}$$
where n is the number of charging records, Tᵢ is the elapsed time recorded in the ith charging record, Aᵢ is the initial charge recorded in the ith charging record, and Bᵢ is the final charge recorded in the ith charging record, both Aᵢ and Bᵢ being expressed as percentages of the full charge.

18. The mobile device of claim 17, wherein the remaining charging time t is calculated using t=(100−X)×C, where X is a current charge expressed as percentage of full charge in the battery of a mobile device, 0<X<100.
